(19) United States
(12) Patent Application Publication
(10) Pub. No.: US 2011/0006817 A1
(43) Pub. Date: Jan. 13, 2011

(54) TRIANGULAR WAVE GENERATOR, SSCG UTILIZING THE TRIANGULAR WAVE GENERATOR, AND RELATED METHOD THEREOF

(76) Inventors: Song-Rong Han, Taipei County (TW); Kuo-Hsiung Wu, Taipei County (TW); Chia-Liang Lai, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/499,781

(22) Filed: Jul. 8, 2009

(51) Int. Cl. H03K 4/06

(52) U.S. Cl. 327/134

(57) ABSTRACT

A triangular wave generator, comprising: a first frequency divider, for utilizing a first positive integer to divide a first frequency of a first periodical signal to generate a first frequency-divided signal; a second frequency divider, for utilizing a second positive integer to divide a second frequency, which equals the first frequency multiplying a third positive integer, of a second periodical signal to generate a second frequency-divided signal; and an up/down counter, for generating a triangular wave first and second frequency-divided frequencies respectively belonging to first and second frequency divided signals; wherein a frequency of the triangular wave equals to the first frequency-divided frequency, and an amplitude of the triangular wave is determined according to a ratio of the first and second frequency-divided frequencies.

### BACKGROUND OF THE INVENTION

1. Field of the Invention

The present invention relates to a triangular generator, a SSCG (Spread Spectrum Clock Generator) utilizing the triangular generator, and a related method thereof, and more particularly relates a triangular generator that can adjust a modulation frequency and an amplitude of a triangular wave, a SSCG utilizing the triangular generator, and a related method thereof.

2. Description of the Prior Art

In an electronic system, an SSCG is provided to generate a spread spectrum clock signal. FIG. 1 is a block diagram of a prior art SSCG 100. As shown in FIG. 1, the SSCG 100 always include a PLL (Phase Locked Loop) 101, which includes a phase detector 103, a charge pump 105, an oscillator 107 and a frequency divider 109. The phase detector 103 is utilized to comparing a reference signal RS and a feedback signal FB, which includes a feedback frequency Fₒᵤₜ, to output a phase detection signal DS. The charge pump 105 decreases or increases the output charge according to the phase detection signal DS to generate a controlling voltage CV. The oscillator 107 determines the oscillating signal OS, which includes an oscillating frequency Fo, according to the controlling voltage CV. The frequency divider 109 frequency-divides the oscillating signal OS to generate the feedback signal FB. Other detail structures and related method are well known by persons skilled in the art, thus they are omitted for brevity here.

Besides the PLL circuit 101, the SSCG 100 may further includes a modulation circuit 102. The modulation circuit 102 is utilized to modulate the oscillating signal OS of the PLL circuit 101 to extend the band width of the PLL circuit 101, such that EMI interference can be reduced and the signal quality is increased. A prior art modulation circuit 102 always includes a triangular wave generator 111, a triangular integration modulator 115 and an adder 117. The triangular wave generator 111 is utilized to generate a triangular signal TW. The triangular integration modulator 115 generates a compensation parameter CP according to a difference between the triangular signal TW and the feedback signal FB. Then the adder 117 adjusts the frequency dividing parameter of the frequency divider 109 according to compensation parameter CP, the original frequency dividing parameter N of the frequency divider 109 and the feedback signal FB, to perform frequency adjusting.

However, such a circuit structure includes the disadvantage thereof. Please refer to FIG. 2, the modulation frequency MF indicates a frequency (and therefore a period) of the triangular wave, and the modulation amplitude indicates the amplitude MA between an upper bound and a lower bound of the triangular wave. In the prior art, the modulation frequency and the frequency amplitude are related (correlated) with each other, and if the modulation frequency decreases, the modulation amplitude decreases correspondingly. On the contrary, if the modulation frequency increases, the modulation amplitude increases correspondingly. Therefore, the complexity of circuit design increases due to the consideration of a balance between modulation frequency and modulation amplitude.

### SUMMARY OF THE INVENTION

Therefore, one objective of the present invention is to provide a triangular wave generator that can unlimitedly adjust the frequency and the amplitude thereof without mutual interference.

One embodiment of the present application provides a triangular wave generator, which comprises: a first frequency divider, for utilizing a first positive integer to frequency-divide a first frequency of a first periodical signal to generate a first frequency divided signal; a second frequency divider, for utilizing a second positive integer to frequency-divide a second frequency of a second periodical signal to generate a second frequency divided signal, wherein the second frequency substantially equals to the first frequency multiplying a third positive integer; and an up/down converter, for generating a triangular wave according to a first frequency-divided frequency of the first frequency divided signal and a second frequency-divided frequency of the second frequency divided signal; wherein a frequency of the triangular wave equals to the first frequency-divided frequency, and an amplitude of the triangular wave is determined by a ratio between the first frequency-divided frequency and the second frequency-divided frequency.

Another embodiment of the present invention discloses a spread spectrum clock generator, which comprises: a PLL circuit, for generating a first periodical signal and a second periodical signal; a modulation signal generator, for generating a modulation signal according to a triangular wave, comprising: a triangular wave generator, for generating a frequency of the triangular wave according to a first frequency of the first periodical signal, and for generating an amplitude of the triangular wave according to a second frequency of the second periodical signal and the first frequency.

Another embodiment of the present invention discloses a triangular wave generating method, comprising: utilizing a first positive integer to frequency-divide a first frequency of a first periodical signal to generate a first frequency divided signal; utilizing a second positive integer to frequency-divide a second frequency of a second periodical signal to generate a second frequency divided signal, wherein the second frequency substantially equals to the first frequency multiplying a third positive integer; and generating a triangular wave, via a triangular wave generator, according to a first frequency-divided frequency of the first frequency divided signal and a second frequency-divided frequency of the second frequency divided signal; wherein a frequency of the triangular wave equals to the first frequency-divided frequency, and an amplitude of the triangular wave is determined by a ratio between the first frequency-divided frequency and the second frequency-divided frequency.

Persons skilled in the art can easily acquire related method according to above mentioned embodiment, thus it is omitted for brevity.

According to above mentioned embodiment, the frequency and the amplitude of the triangular wave can be unlimitedly adjusted without interference for each other, thereby enables the modulation circuit utilizing the triangular wave generator to adjust the modulation frequency and modulation amplitude unlimitedly and independently.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a prior art PLL system 100.

FIG. 2 is a schematic diagram for the modulation frequency for a triangular wave.

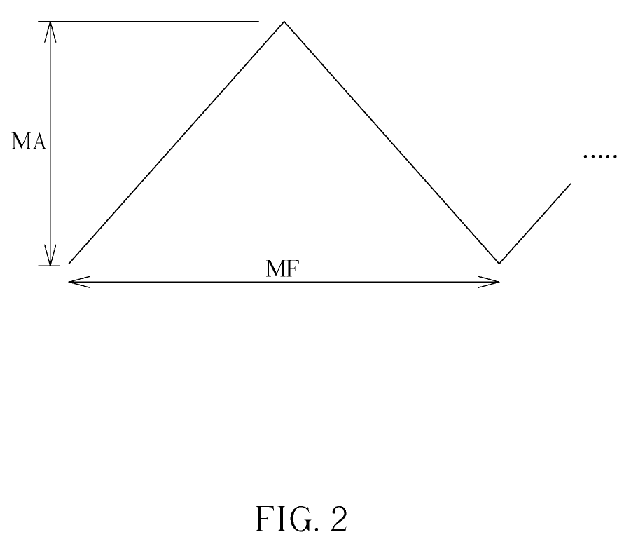

FIG. 3 is a circuit diagram illustrating a triangular wave generator, a modulation circuit and a SSCG according to an embodiment of the present invention.

FIG. 4 is a schematic diagram illustrating that how the up/down converter generates a triangular wave.

FIG. 5 illustrates a triangular wave generating method corresponding to the circuit diagram in FIG. 3.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

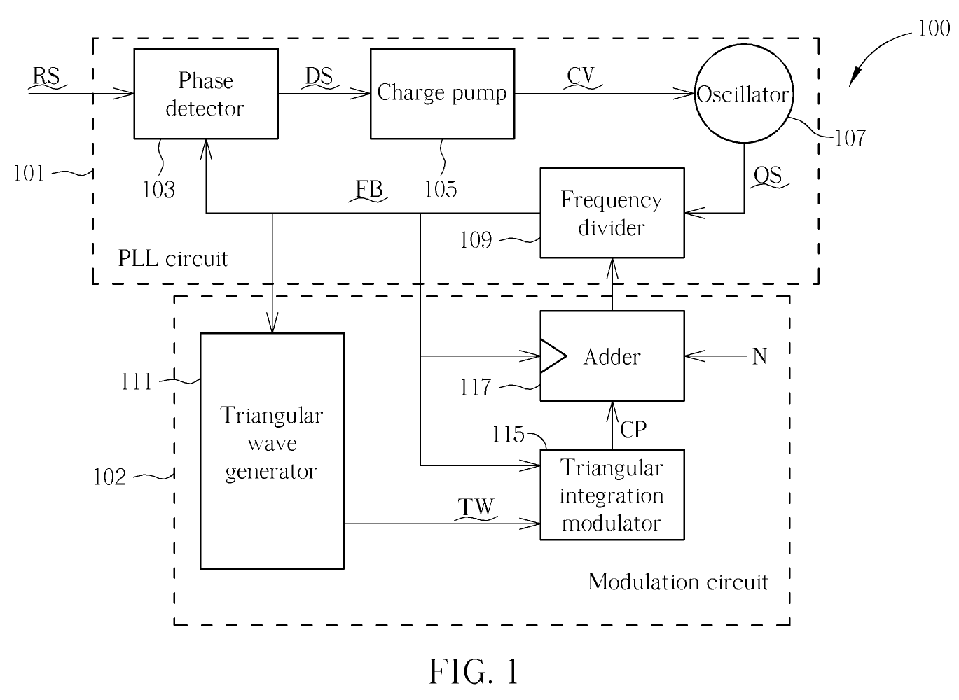

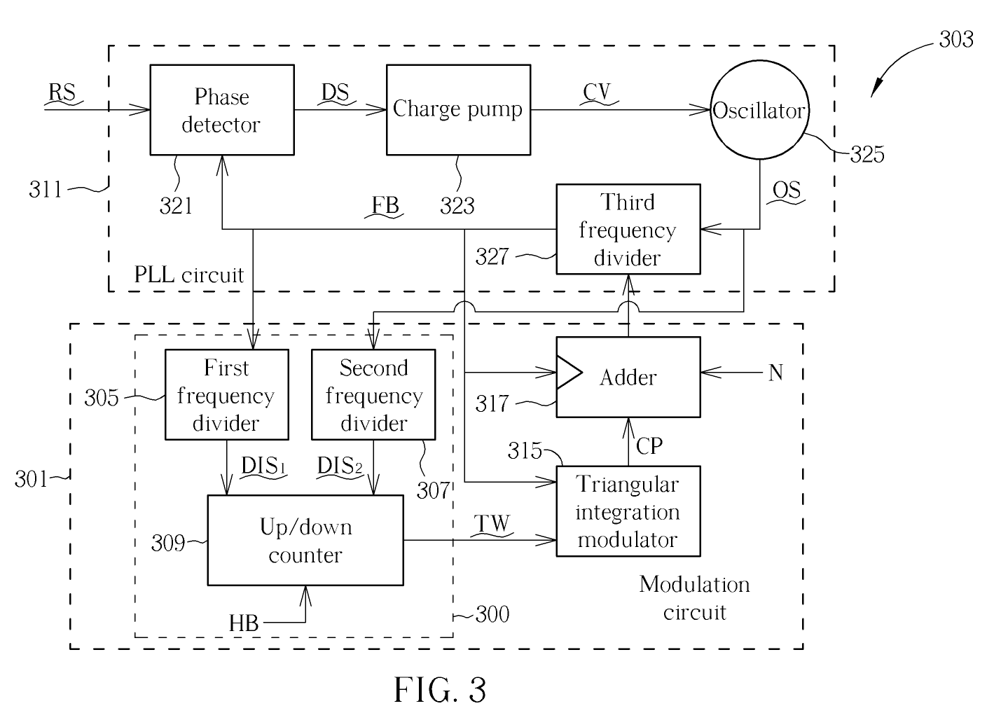

FIG. 3 is a circuit diagram illustrating a triangular wave generator 300, a modulation circuit 301 and a SSCG 303 according to an embodiment of the present invention. As shown in FIG. 3, the triangular wave generator 300 according to an embodiment of the present invention includes a first frequency divider 305, a second frequency divider 307 and an up/down counter 309. The first frequency divider 305 includes a first frequency dividing parameter L (a positive integer), for frequency-dividing the feedback signal FB to generate a first frequency divided signal DIS₁ with a first frequency-divided frequency. The second frequency divider 307 includes a second frequency dividing parameter M (a positive integer), for frequency-dividing the oscillating signal OS to generate a second frequency divided signal DIS₂ with a second frequency-divided frequency. The up/down counter 309 is used for generating a triangular wave, and a counting frequency (a modulation frequency of a triangular wave)of the up/down counter 309 substantially equals to the first frequency-divided frequency of the first frequency divided signal DIS₁. Also, a distance between an upper bound and a lower bound (the amplitude MA of the triangular wave) is determined by a ratio between the first frequency-divided frequency and the second frequency-divided frequency. The PLL circuit 311 also includes a phase detector 321, a charge pump 323, an oscillator 325 and a third frequency divider 327, the same as the PLL circuit 101 in FIG. 1.

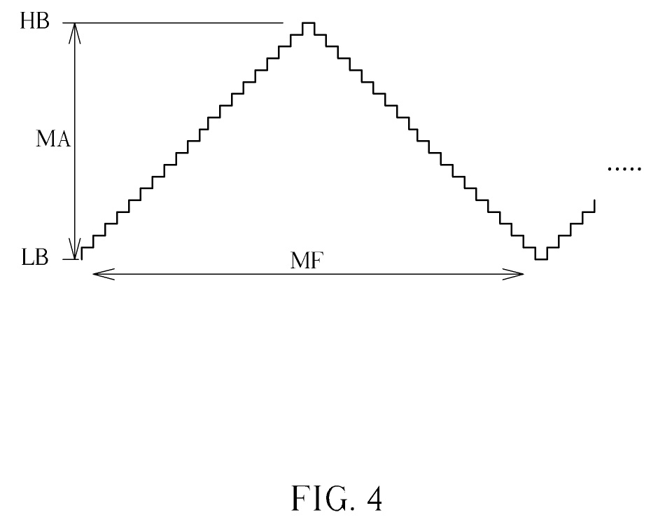

The triangular wave generating operation of the up/down counter 309 is explained via FIG. 4.As shown in FIG. 4, an initial value is given to determine one of the upper bound HB and the lower bound LB (i.e. the first extreme value or the second extreme value). The up/down counter 309 counts up or counts down from the initial value (i.e. the upper bound HB or the lower bound LB) according to a positive edge or a negative edge of the first frequency divided signal DIS₁. Besides, the up/down counter 309 determines counting numbers and counting intervals of one half period of the feedback signal FB according to the second frequency-divided frequency of the second frequency divided signal DIS₂. That is, the signal DIS₁ controls alternating between counting up and down, and the signal DIS₂ triggers counting of the up/down counter 309. Briefly, the first frequency-divided frequency of the first frequency divided signal DIS₁ is determined first, then an upper bound or a lower bound is selected, and then the counting interval is determined according to the second frequency-divided frequency of the second frequency divided signal DIS₂. By this way, the ratio between the first frequency-divided frequency and the second frequency-divided frequency can determine amplitude of the triangular wave.

In more detail, the counting frequency of the up/down counter 309 can be determined by Equation (1).

(OSF/N)/L=MF Equation (1)

Wherein OSF is a frequency of the output signal OS, N is a third frequency dividing parameter of the third frequency divider 321 in for the PLL circuit 311, L is a first frequency dividing parameter of the first frequency divider 305, and MF is a counting frequency of the up/down counter 309.

Also, two extreme values of the up/down counter 309 (upper bound HB and lower bound LB) can be determined by Equation (2.

((OSF/M)/((OSF/N)/L))/2=MA=HB−LB Equation (2)

In one embodiment, the upper bound is determined via giving a parameter to the up/down counter 309, thus an initial value can be given to determine the upper bound. If frequency OSF of the oscillating signal OS, and the third frequency-dividing parameter N of the third frequency divider 327 are fixed, the triangular wave amplitude (HB−LB) can be determined via varying the first frequency dividing parameter L and the second frequency dividing parameter M (i.e. varying a ratio between the first frequency dividing parameter and the second frequency dividing parameter). For example, if the oscillating signal OS is supposed to have a 1 GHz frequency, the feedback signal FB is supposed to have a 10 MHz frequency, the first frequency dividing parameter L is supposed to be 332, the third frequency-dividing parameter N is supposed to be 100, and the upper bound HB is supposed to be 470, then the modulation frequency is 10 MHz/332=30.12 KHz, the lower bound LB=HB−(16600/M). If M is set to 100, then the lower bound LB=304 and the modulation amplitude equals to 470−304=166. If M is set to 50, then the lower bound LB=138 and the modulation amplitude equals to 470−138=332. Accordingly, without varying the second modulation parameter M, the modulation amplitude can be changed via changing the second frequency dividing parameter M. On the contrary, if the second frequency dividing parameter M is fixed and vary the first frequency dividing parameter L, the modulation frequency can be varied without varying the modulation amplitude. As described above, the up/down counter 309 will transmit the triangular wave TW to a triangular integration modulator 315 after generating the triangular wave TW, and then the triangular integration modulator 315 will send a compensation parameter CP to the adder 317. The following operation is described in related description of FIG. 1, thus it is omitted for brevity here.

It should be noted that the above-mentioned circuit structure is only for example and does not mean to limit the scope of the present application. The triangular wave generator according to the embodiment of the present application is not limited to be utilized in a modulation circuit. Also, the modulation circuit utilizing the triangular wave generator according to the embodiment of the present application is not limited to a PLL.

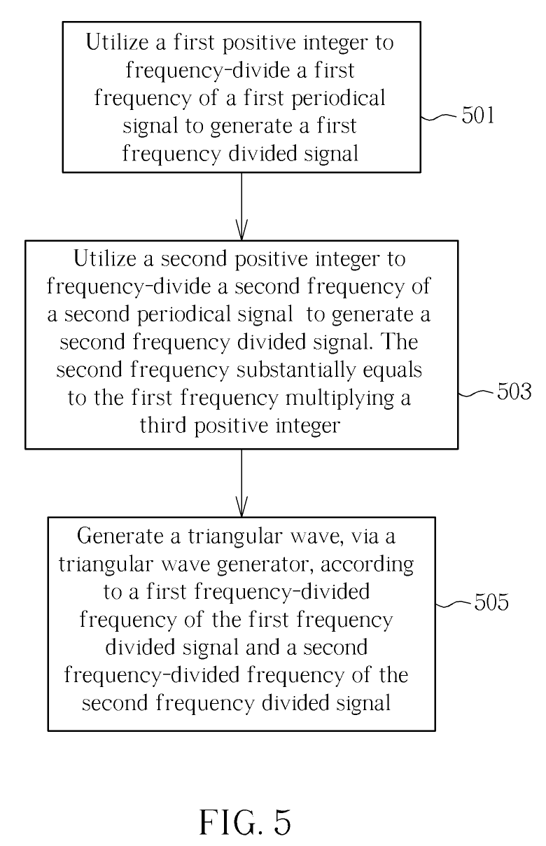

According to the embodiment shown in FIG. 3, a corresponding triangular wave generating method can be acquired, which includes the steps shown in FIG. 5:

Step 501

Utilize a first positive integer to frequency-divide a first frequency of a first periodical signal (for example, the feedback signal FB of FIG. 3) to generate a first frequency divided signal (for example, the first frequency divided signal DIS₁ in FIG. 3)

Step 503

Utilize a second positive integer to frequency-divide a second frequency of a second periodical signal (for example, the oscillating signal OS of FIG. 3) to generate a second frequency divided signal (for example, the second frequency divided signal DIS₂ in FIG. 3) The second frequency substantially equals to the first frequency multiplying a third positive integer.

Step 505

Generate a triangular wave, via a triangular wave generator, according to a first frequency-divided frequency of the first frequency divided signal and a second frequency-divided frequency of the second frequency divided signal.

According to above mentioned embodiment, the frequency and the amplitude of the triangular wave can be unlimitedly and independently adjusted without interference for each other, thereby enables the modulation circuit utilizing the triangular wave generator to adjust the modulation frequency and modulation amplitude unlimitedly with higher flexibility.

Those skilled in the art will readily observe that numerous modifications and alterations of the device and method may be made while retaining the teachings of the invention.

What is claimed is:

1. A triangular wave generator, comprising:
a first frequency divider, for utilizing a first positive integer to frequency-divide a first frequency of a first periodical signal to generate a first frequency divided signal;
a second frequency divider, for utilizing a second positive integer to frequency-divide a second frequency of a second periodical signal to generate a second frequency divided signal, wherein the second frequency substantially equals to the first frequency multiplying a third positive integer; and
an up/down converter, for generating a triangular wave according to a first frequency-divided frequency of the first frequency divided signal and a second frequency-divided frequency of the second frequency divided signal;
wherein a frequency of the triangular wave equals to the first frequency-divided frequency, and amplitude of the triangular wave is determined by a ratio between the first frequency-divided frequency and the second frequency-divided frequency.

2. The triangular wave generator in claim 1, wherein the up/down converter determines a first extreme value of the amplitude according to an initial value, and a second extreme value of the amplitude is determined according to the initial value and the ratio.

3. The triangular wave generator in claim 2, wherein the up/down converter counts up the initial value according to one of a positive edge and a negative edge of the first frequency-divided frequency.

4. The triangular wave generator in claim 1, wherein the up/down converter determines counting numbers and counting intervals of one half period of the first periodical signal according to the second frequency-divided frequency.

5. The triangular wave generator in claim 2, wherein the second extreme value is a minimum value of the amplitude when the first extreme value is a maximum value of the amplitude, where a difference between the first extreme value and the second extreme value is determined by the ratio.

6. The triangular wave generator in claim 5, wherein the up/down converter counts down the initial value according to one of a positive edge and a negative edge of the first frequency-divided frequency, when the first extreme value is a maximum value of the amplitude.

7. A spread spectrum clock generator, comprising:
a PLL circuit, for generating a first periodical signal and a second periodical signal;
a modulation signal generator, for generating a modulation signal according to a triangular wave, comprising:
a triangular wave generator, for generating a frequency of the triangular wave according to a first frequency of the first periodical signal, and for generating an amplitude of the triangular wave according to a second frequency of the second periodical signal and the first frequency.

8. The spread spectrum clock generator in claim 7, wherein the modulation signal is utilized to adjust a frequency dividing parameter, where the PLL circuit adjusts the first frequency according to the frequency dividing parameter and the second frequency.

9. The spread spectrum clock generator in claim 7, wherein the triangular wave generator comprises:
a first frequency divider, for utilizing a first positive integer to frequency-divide the first frequency of the first periodical signal to generate a first frequency divided signal;
a second frequency divider, for utilizing a second positive integer to frequency-divide the second frequency of the second periodical signal to generate a second frequency divided signal, wherein the second frequency substantially equals to the first frequency multiplying a third positive integer; and
an up/down converter, for generating the triangular wave according to a first frequency-divided frequency of the first frequency divided signal and a second frequency-divided frequency of the second frequency divided signal;
wherein the frequency equals to the first frequency-divided frequency, and the amplitude is determined by a ratio between the first frequency-divided frequency and the second frequency-divided frequency.

10. The spread spectrum clock generator in claim 9, wherein the up/down converter determines a first extreme value of the amplitude according to an initial value, and a second extreme value of the amplitude is determined according to the initial value and the ratio.

11. The spread spectrum clock generator in claim 10, wherein the up/down converter counts up the initial value according to one of a positive edge and a negative edge of the first frequency-divided frequency.

12. The spread spectrum clock generator in claim 9, wherein the up/down converter determines counting numbers and counting intervals of one half period of the first periodical signal according to the second frequency-divided frequency.

13. The spread spectrum clock generator in claim 10, wherein the second extreme value is a minimum value of the amplitude when the first extreme value is a maximum value of the amplitude, where a difference between the first extreme value and the second extreme value is determined by the ratio.

14. The spread spectrum clock generator in claim 13, wherein the up/down converter counts down the initial value according to one of a positive edge and a negative edge of the first frequency-divided frequency, when the first extreme value is a maximum value of the amplitude.

15. A triangular wave generating method, comprising:
utilizing a first positive integer to frequency-divide a first frequency of a first periodical signal to generate a first frequency divided signal;
utilizing a second positive integer to frequency-divide a second frequency of a second periodical signal to generate a second frequency divided signal, wherein the second frequency substantially equals to the first frequency multiplying a third positive integer; and
generating a triangular wave, via a triangular wave generator, according to a first frequency-divided frequency of the first frequency divided signal and a second frequency-divided frequency of the second frequency divided signal;
wherein a frequency of the triangular wave equals to the first frequency-divided frequency, and amplitude of the triangular wave is determined by a ratio between the first frequency-divided frequency and the second frequency-divided frequency.

16. The triangular wave generating method in claim 15, wherein a first extreme value of the amplitude is determined according to an initial value, and a second extreme value of the amplitude is determined according to the initial value and the ratio.

17. The triangular wave generating method in claim 15, further comprising counting up the initial value according to one of a positive edge and a negative edge of the first frequency-divided frequency.

18. The triangular wave generating method in claim 15, further comprising determining counting numbers and counting intervals of one half period of the first periodical signal according to the second frequency-divided frequency.

19. The triangular wave generating method in claim 16, wherein the second extreme value is a minimum value of the amplitude when the first extreme value is a maximum value of the amplitude, where a difference between the first extreme value and the second extreme value is determined by the ratio.

20. The triangular wave generating method in claim 19, further comprising counting down the initial value according to one of a positive edge and a negative edge of the first frequency-divided frequency, when the first extreme value is a maximum value of the amplitude.
